(19) United States
(12) Patent Application Publication
(10) Pub. No.: US 2017/0359896 A1
(43) Pub. Date: Dec. 14, 2017

(54) APPARATUS AND METHOD FOR CONFIGURING A VERTICAL INTERCONNECTION ACCESS AND A PAD ON A 3D PRINTED CIRCUIT UTILIZING A PIN

(71) Applicant: Board of Regents, The University of Texas System, Austin, TX (US)

(72) Inventors: Chi Yen Kim, El Paso, TX (US); Ryan Wicker, El Paso, TX (US); Eric MacDonald, El Paso, TX (US); David Espalin, El Paso, TX (US)

(21) Appl. No.: 15/618,256

(22) Filed: Jun. 9, 2017

Related U.S. Application Data
(60) Provisional application No. 62/349,908, filed on Jun. 14, 2016.

(51) Int. Cl. H05K 1/11; H01R 12/57; H05K 3/40; H05K 3/10

(52) U.S. Cl. CPC H05K 1/113; H05K 3/103; H01R 12/57; H05K 3/4007; H05K 3/4046; H05K 2201/10242; H05K 2201/10303; H05K 2201/10257

(57) ABSTRACT

A 3D printed circuit apparatus includes a 3D printed circuit having a surface layer and one or more wires embedded under the surface layer, and a conductive metal pin that is cut to a desired length and inserted into the 3D printed circuit in order to attain contact with the wire or wires embedded under the surface layer.

### CROSS-REFERENCE TO PROVISIONAL APPLICATION

This nonprovisional patent application claims the benefit under 35 U.S.C. §119(e) and priority to U.S. Provisional Patent Application Ser. No. 62/349,908, filed on Jun. 14, 2016, entitled “Apparatus and Method for Configuring a Vertical Interconnection Access and a Pad on a 3D Printed Circuit Utilizing a Pin,” which is hereby incorporated herein by reference in its entirety.

### TECHNICAL FIELD

Embodiments are related to the fields of 3D printing, additive manufacturing, layer manufacturing, rapid prototyping, layer-wise fabrication, solid freeform fabrication, and direct digital manufacturing. Embodiments also relate to new and useful methods, systems, and devices for manufacturing a VIA (Vertical Interconnection Access) and a pad on a 3D printed circuit.

### BACKGROUND

3D printers enable the production of electronic circuits by directly adding conductive ink or metal wires as interconnect between components. For the 3D printed circuit to attain the same functionality and interconnect complexity as a traditional PCB board, however, the 3D printed circuit must have a multilayered structure to avoid collisions and improve routability. By configuring a dense multilayered electronic circuit, average line length is reduced to avoid accumulative resistance and volumetric efficiencies are increased.

A multilayered electronic circuit is composed of not only uniplanar conductive connection, but also a VIA (Vertical Interconnection Access) among two or more layers. Conductive inks are widely used, for example, in 3D printing, but have high resistances due to the limits imposed on curing by the polymer substrate. (Note that other terms used synonymously to refer to 3D printing include additive manufacturing, layer manufacturing, rapid prototyping, layer-wise fabrication, solid freeform fabrication, and direct digital manufacturing.)

As a result, inks reduce performance and are not suitable for use as VIAs despite the associated manufacturing flexibility and ease-of-use. Also, many electronic devices are made for surface mounting, so a pad—flush to the surface—must be provided on which the components are mounted. Since conductive inks spread easily on 3D printed surfaces, it is difficult to configure a thin pad for mounting.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings and abstract as a whole.

It is, therefore, one aspect of the disclosed embodiments to provide for an improved 3D printed circuit apparatus.

It is another aspect of the disclosed embodiments to provide for a 3D printed circuit having multiple layers including a surface layer and one or more wires embedded under the surface layer.

It is yet another aspect of the disclosed embodiments to provide a conductive metal component (e.g., a pin, a hollow tube, a section of a tube, a folded sheet, etc.) for use in configuring or rendering a 3D printed circuit apparatus.

It is yet another aspect of the disclosed embodiments to provide a conductive pad that can be formed on a surface layer of the 3D printed circuit apparatus.

The aforementioned aspects and other objectives and advantages can now be achieved as described herein. A 3D printed circuit apparatus is disclosed, which includes a 3D printed circuit having a surface layer and one or more wires (e.g., a single wire or a group of wires) embedded under the surface layer, and a conductive metal component (e.g. a pin) that is cut to a desired length and inserted into the 3D printed circuit in order to attain contact with the wire or wires embedded under the surface layer. The conductive metal pin can be configured as, for example, a grooved pin that is cleaved at the bottom to contact and accommodate an under layer embedded wire on two sides to decrease the electrical resistance. By accommodating the under laying wire, the pin (or other conductive component such as a pin, a hollow tube, a section of a tube, a folded sheet, etc.) can be submerged further into the substrate to increase the mechanical adhesion of the pin to the substrate. Furthermore, the interrupted print can continue unobstructed to further contain the pin and provide additional mechanical stability. The conductive metal pin (i.e., or other component) can be cut from a metal sheet or a metal roll to the desired length.

The wire or wires can be placed into a groove so that the conductive component (e.g., a pin, a hollow tube, a section of a tube, a folded sheet, etc.) functions as a VIA. A pad can also be configured from a remaining excess portion of the conductive metal pin deposited (e.g., bent parallel to the printed substrate surface) on the surface layer, providing a contact pad. In some example embodiments, the pad can be configured as a pad for a SMD (Surface Mount Device) for a lead on an electrical component or as a continuation point for a new wire on the surface layer. The 3D printed circuit can also be configured as a mid-build 3D printed multi-layered electronic circuit.

In still other example embodiments, a method or process of configuring a 3D printed circuit apparatus can be implemented, which includes steps or operations such as: (1) configuring a 3D printed circuit with a surface layer and at least one wire embedded under the surface layer; (2) cutting a conductive metal component to a desired length; and (3) inserting the conductive metal component into the 3D printed circuit in order to attain contact with the at least one wire embedded under the surface layer. In some example embodiments, an additional step or operation can be implemented involving, for example, a step/operation of configuring a pad from a remaining excess portion of the conductive metal component deposited above the surface layer, the pad inserted on the surface layer. As indicated previously, the conductive metal component can be, for example, a pin, a hollow tube, a section of a tube, a folded sheet, a grooved component, and so on.

To resolve the difficulties of fabricating a VIA and placing a pad on a mid-build 3D printed multi-layered electronic circuit, the disclosed embodiments introduce the use of a conductive metal pin. A process or method can thus be implemented, which utilizes a grooved pin that is cut from a metal sheet or a roll to a desired length, and then inserted into the 3D printed circuit in order to produce an electrical and physical contact with the wires embedded under the surface layer.

This approach allows for two types of connections. By placing multiple wires into the groove, this acts as a VIA. Additionally, depositing the remaining excess pin above the surface after inserting on the surface becomes a pad for surface mount devices such as SSOP package SMD device or to connect to a wire at the current top surface. Since the pin is directly made from solid sheet or roll, the electric resistance is the same as a solid metal, which cannot be achieved with conductive ink due to the additional binders and required chemistry. Cutting the pin to a desired size provides an additional advantage to a circuit designer so that the designer can design, for example, artwork with a high routing density as achieved on, for example, PCB boards and to variable depths.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a schematic diagram depicting a vertical interconnect fabrication connection and a surface pad connection, in accordance with an example embodiment;

FIG. 2 illustrates a system for implementing a cutting fabrication process, in accordance with an example embodiment;

FIG. 3 illustrates a system for implementing a pin grooving method, in accordance with an example embodiment;

FIGS. 4A-4F illustrate a process or method for installing the pin into a circuit, in accordance with an example embodiment; and

FIGS. 5A-5F illustrate a process or method for configuring a pad, in accordance with an example embodiment.

### DETAILED DESCRIPTION

The particular values and configurations discussed in these non-limiting examples can be varied and are cited merely to illustrate at least one embodiment and are not intended to limit the scope thereof.

The embodiments will now be described more fully hereinafter with reference to the accompanying drawings, in which illustrative embodiments of the invention are shown. The embodiments disclosed herein can be embodied in many different forms and should not be construed as limited to the embodiments set forth herein; rather, these embodiments are provided so that this disclosure will be thorough and complete, and will fully convey the scope of the invention to those skilled in the art. For example, preferred and alternative embodiments are disclosed herein.

Additionally, like numbers refer to identical, like, or similar elements throughout, although such numbers may be referenced in the context of different embodiments. As used herein, the term “and/or” includes any and all combinations of one or more of the associated listed items.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosed example embodiments relate to the fields of 3D printing, additive manufacturing, layer manufacturing, rapid prototyping, layer-wise fabrication, solid freeform fabrication, and direct digital manufacturing. The disclosed example embodiments also relate to new and useful methods, systems, and devices for manufacturing a VIA (Vertical Interconnection Access) and a pad on a 3D printed circuit, as discussed below.

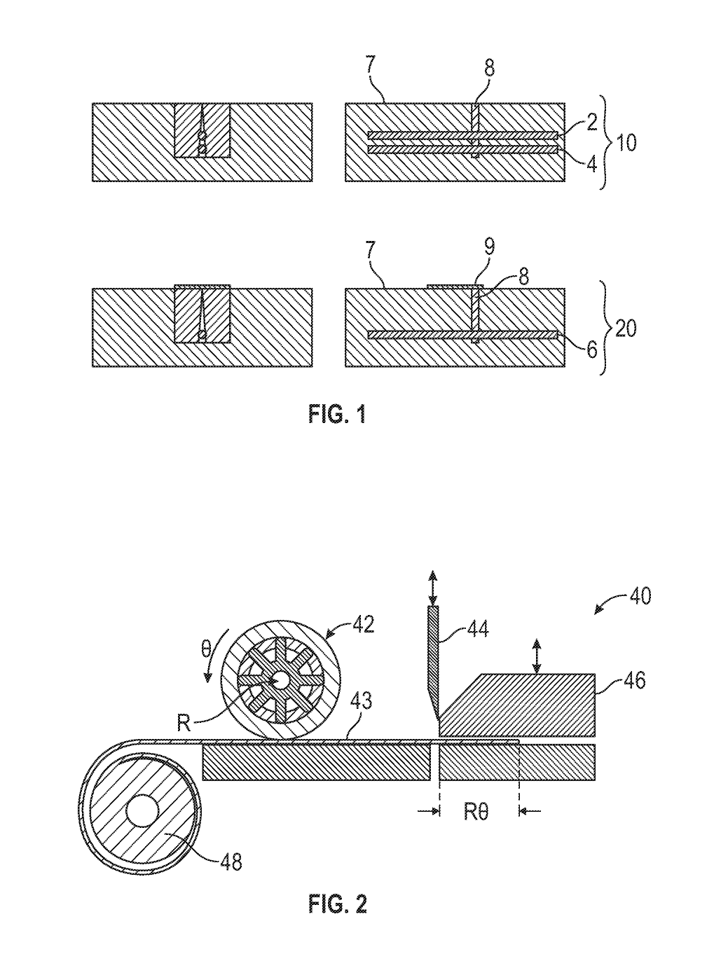

FIG. 1 illustrates a schematic diagram depicting a vertical interconnect fabrication connection 10 and a surface pad connection 20, in accordance with example embodiments. To resolve the difficulties of fabricating a VIA (Vertical Interconnect Access) and placing a pad on a mid-build 3D printed multi-layered electronic circuit, the disclosed example embodiments introduce the use of a conductive metal pin 8. In detail, this approach makes a grooved conductive metal pin, which can be cut from a metal sheet or roll to a desired length, and inserted into a 3D printed circuit in order to have contact with the wires embedded under the surface layer 7. Note that as utilized herein, the term VIA (Vertical Interconnect Access) refers to an electrical connection between one or more layers in a physical electronic circuit that can, for example, extend through the plane of one or more adjacent layers.

In some example embodiments, commercial off-the-shelf pins of various lengths can be utilized rather than having to cut the metal sheet or roll to the desired length. Note that although example embodiments refer to the use of a conductive metal pin, other conductive metal components can be utilized in place of or in addition to such a metal pin. Examples of other conductive metal components that can be utilized in other embodiments include, for example, a hollow tube, a section of a tube, a folded sheet, etc.

The approach described herein therefore can provide two types of connections 10 and 20, as shown in FIG. 1. Note that a front view and a side view of each connection 10, 20 are shown in FIG. 1. The vertical connection 10 configuration shown in FIG. 1 generally includes two wires 2 and 4 and the conductive metal pin 8. The surface pad connection 20 configuration includes a single wire 6 and the pin extends from the wire 6 to the pad located on the surface layer 7.

The pad can be in some example embodiments, a small surface of copper in, a PCT that allows soldering the component to the board. Such a pad may be, for example, a piece of copper where the pins of the component are mechanically supported and soldered. There are generally 2 types of pads: thru-hole (or through hole) and SMD (Surface Mount Device) type pads. It can be appreciated of course, that the pad may be composed of other types of material, not just copper, and may be configured in a variety of shapes and arrangements. The reference above to copper and thru-hole and SMD is provided herein for exemplary purposes only and should not be considered a limiting feature of the disclosed embodiments. In general, the pad can be configured as a pad for an SMD and/or a pad that is joinable to other components.

By placing multiple wires such as wires 2 and 4 into the groove, this acts as a VIA providing a stable mechanical connection with reduced electrical resistance. Additionally, depositing the remaining excess pin 8 above the surface 7 after inserting on the surface 7 becomes the pad 9 for surface mount devices such as an SSOP (Shrink Small-Outline Package) SMD device or a connection for a new wire on the surface layer. Since the pin is directly made from solid sheet or roll, the electric resistance is the same as a solid metal, which cannot be achieved with conductive inks due to the additional binders and required chemistry. Cutting the pin 8 to a desired size provides an additional advantage to a circuit designer so that the designer may design artwork with a high routing density as achieved on, for example, PCB boards and to interconnect wires at varying depths in a single circuit print.

FIG. 2 illustrates a system 40 for implementing a cutting fabrication process, in accordance with an example embodiment. The system 40 can include a feeder roller 42 that abuts a metal sheet 43 (or metal roll). A cutting blade 44 is located to the right of the feeder roller 42 and touches a holding block 46. A metal sheet spool 48 can be utilized to spool the metal 43 or metal roll.

The example embodiments can be divided into two major types of processes: (1) making the pin from metal sheet or coil and inserting it into the 3D printed circuit either directly into the substrate or (2), alternatively, inserting it into an intentional cavity sized appropriately for the pin. The pin making process can involve two sub processes. At the beginning of the process, a machine cuts out a piece of metal strip from the metal sheet 43 (e.g., or a metal roll) to the desired width. The width of the pin can be determined by circuit design and can allow for a tradeoff between conductivity (e.g., larger via cross-section) and routing density (e.g., smaller required area on the surface). FIG. 2 therefore illustrates the cutting process.

When the feeder roller 42 turns 8 degrees, an rθ length of metal resource is fed into the cutter. After placing the material into the cutter, the cutting blade 44 makes the cut while a block holds the metal that was fed. This method enables the strip to be at least 20 mil (e.g., ˜500 microns) in width. Gripping the part during cutting helps slide a piece narrowly and accurately because the cutting position is fixed during cutting. Therefore, when a pin of d width is needed for VIA for a 3D printed circuit, the designed system pushes a metal sheet into the cutter by turning a feeder roller about d/R angle, and then a block holds down the sheet by pressing down on the part, which is then severed with the blade. The cut strip can then be moved to the next section where the groove cutting process is accomplished.

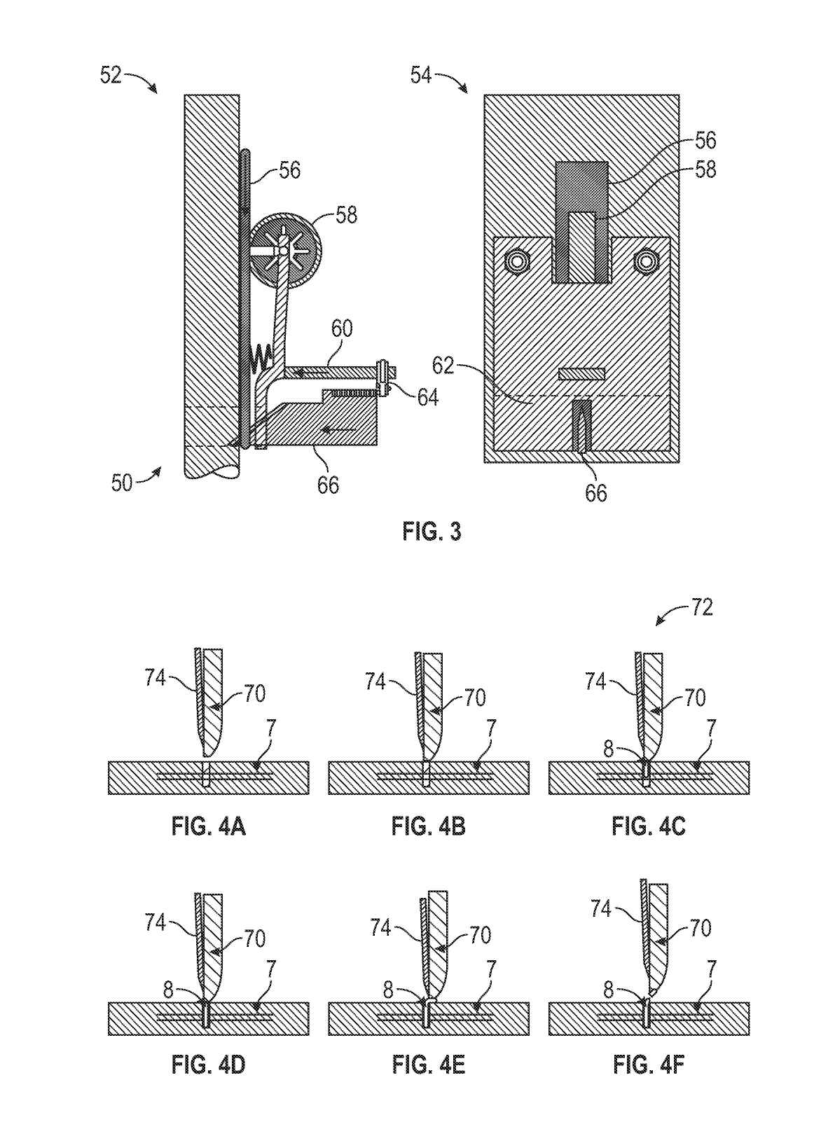

FIG. 3 illustrates a system 50 for implementing a pin grooving method, in accordance with an example embodiment. A side view 52 and a top view 54 of the system are shown in FIG. 3. The system 50 includes a pin strip 56 disposed adjacent a roller 58. System 58 also includes a push rod 60, a push bar 62, and a motor 64. According to the gap between wires embedded on different layers and the gauge of the wires, the depth of the groove on the pin can vary. To adjust the depth of the groove, an inclined blade 66 can be employed. The depth of the groove can be determined by the insertion distance of the blade 66. Since the width of the pin is narrow, the approach shown in FIG. 3 adds the push bar 62, which presses onto the strip 56 during the cutting of the groove. After grooving, the pin is moved down to an insertion nozzle.

FIGS. 4A-4F illustrate a process or method 72 for installing the pin into a circuit, in accordance with an example embodiment. FIGS. 4A-4F illustrate an approach involving pin insertion for VIA. There are two kinds of mounting methods. The first is pin insertion for VIA as shown in FIG. 4C. A nozzle 70, which discharges the pin 8, is mounted at the tool head, which is movable. When the pin 8 is to be placed at a certain targeted VIA location, the nozzle 70 approaches the pre-designed hole in which the pin 8 will be inserted. After inserting the pin 8 into the hole, the nozzle 70 is shifted aside and a knife 74 cuts the excess material.

When the pin 8 is inserted, wires 7 that re already embedded on the surface and layers below, will land in the groove of the pin 8, resulting in connectivity between two different circuits on two different layers via a VIA. If the width of the pin 8 is smaller than that of the hole, the pin 8 can be heated so that it may be placed in the hole. Applying a liquid adhesive or bending the remaining edge, to form a convex shape, can fix the pin 8 in place.

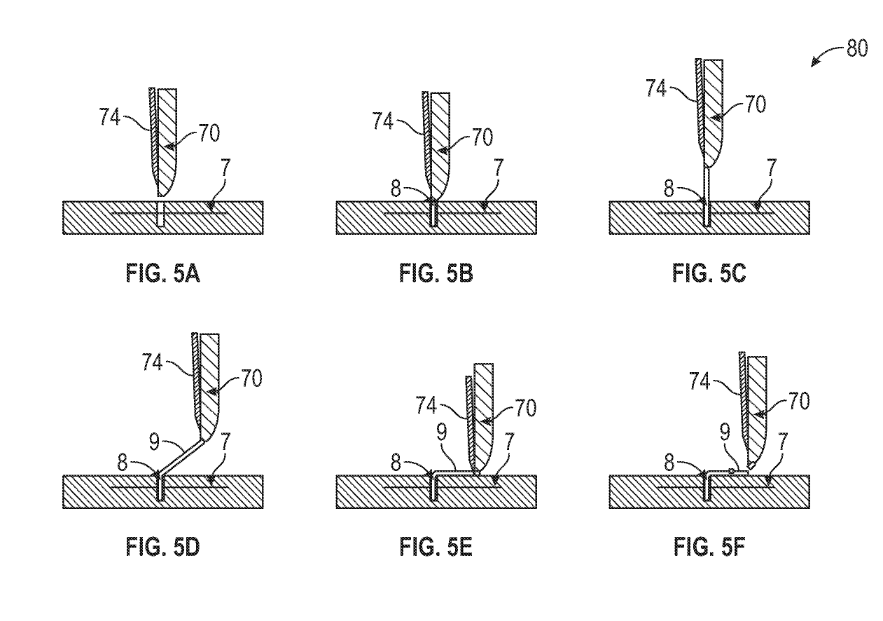

FIGS. 5A-5F illustrate a process or method 80 for configuring the pad 9, in accordance with an example embodiment. In the second mounting method, instead of cutting the excess metal above the surface after inserting, the metal is continuously dispensed while the head is extracted from the surface. The metal can be dispensed to the desired length, such as the pad 9 to mount electronic devices, and then folded over in a radial motion towards the surface then cut. Heat can then be applied to the metal in order to melt the surrounding polymer to adhere to the pin 8 and solidify, fixing the pin 8 and the pad 9 in place. FIG. 5 illustrates a procedure for fabricating a pad 9 involving steps A, B, C, D, E, and F, in accordance with an example embodiment.

Based on the foregoing, it can be appreciated that a number of example embodiments are disclosed. For example, in one embodiment, a 3D printed circuit apparatus can be configured, which includes a 3D printed circuit having a surface layer and at least one wire embedded under the surface layer, and a conductive metal pin that is cut to a desired length and inserted into (e.g., possibly with an intentional cavity appropriately sized for the pin or directly in to the substrate) the 3D printed circuit in order to attain contact with the at least one wire embedded under the surface layer. The conductive metal pin can in some embodiments comprise a grooved pin. In another embodiment, the conductive metal pin can be cut from a metal sheet or a metal roll to the desired length. In still another example embodiment, the conductive metal pin can function as a VIA.

In some example embodiments, a pad can be configured from the remaining excess portion of the conductive metal pin deposited above the surface layer, the pad inserted on the surface layer. The pad can comprise, for example, a pad for a surface mount device and/or a pad that is joinable to other components. In addition, in some example embodiments, the 3D printed circuit can comprise a mid-build 3D printed multi-layered electronic circuit.

In still other example embodiments, a method or process of configuring a 3D printed circuit apparatus can be implemented. Such a method or process can include steps or operations such as (1) configuring a 3D printed circuit with a surface layer and at least one wire embedded under the surface layer; (2) cutting a conductive metal component to a desired length; and (3) inserting the conductive metal component into the 3D printed circuit in order to attain contact with the at least one wire embedded under the surface layer. In some example embodiments, an additional step or operation can be implemented involving, for example, a step/operation of configuring a pad from a remaining excess portion of the conductive metal component deposited above the surface layer, the pad inserted on the surface layer. As indicated previously, the conductive metal component can be, for example, a pin, a hollow tube, a section of a tube, a folded sheet, a grooved component, and so on.

It will be appreciated that variations of the above-disclosed and other features and, functions, or alternatives thereof, may be desirably combined into many other different systems or applications. It will also be appreciated various presently unforeseen or unanticipated alternatives, modifications, variations or improvements therein may be subsequently made by those skilled in the art, which are also intended to be encompassed by the following claims.

What is claimed is:

1. A 3D printed circuit apparatus, comprising:
a 3D printed circuit having a surface layer and at least one wire embedded under said surface layer; and
a conductive metal component that is cut to a desired length and inserted into said 3D printed circuit in order to attain contact with said at least one wire embedded under said surface layer.

2. The apparatus of claim 1 wherein said conductive metal component comprises a pin.

3. The apparatus of claim 1 wherein said conductive metal component comprises a hollow tube.

4. The apparatus of claim 1 wherein said conductive metal component comprises a section of a tube.

5. The apparatus of claim 1 wherein said conductive metal component comprises a folded sheet.

6. The apparatus of claim 1 wherein said conductive metal component comprises a grooved component.

7. The apparatus of claim 1 wherein said conductive metal component is cut from a metal sheet or a metal roll to said desired length.

8. The apparatus of claim 1 wherein said conductive metal component functions as a VIA.

9. The apparatus of claim 1 further comprising a pad configured from a remaining excess portion of said conductive metal component deposited above said surface layer, said pad inserted on said surface layer.

10. The apparatus of claim 9 wherein said pad comprises a pad for a surface mount device and/or a pad that is joinable to other components.

11. The apparatus of claim 1 wherein said 3D printed circuit comprises a mid-build 3D printed multi-layered electronic circuit.

12. A 3D printed circuit apparatus, comprising:
a 3D printed circuit having a surface layer and at least one wire embedded under said surface layer; and
a conductive metal pin that is cut to a desired length and inserted into said 3D printed circuit in order to attain contact with said at least one wire embedded under said surface layer.

13. The apparatus of claim 12 wherein said conductive metal pin comprises a grooved pin.

14. The apparatus of claim 12 wherein said conductive metal pin is cut from a metal sheet or a metal roll to said desired length.

15. The apparatus of claim 12 wherein said conductive metal pin functions as a VIA.

16. The apparatus of claim 12 further comprising a pad configured from a remaining excess portion of said conductive metal pin deposited above said surface layer, said pad inserted on said surface layer.

17. The apparatus of claim 12 wherein said pad comprises a pad for a surface mount device and/or a pad that is joinable to other components.

18. The apparatus of claim 17 wherein said 3D printed circuit comprises a mid-build 3D printed multi-layered electronic circuit.

19. A method of configuring a 3D printed circuit apparatus, comprising:
configuring a 3D printed circuit with a surface layer and at least one wire embedded under said surface layer;
cutting a conductive metal component to a desired length; and
inserting said conductive metal component into said 3D printed circuit in order to attain contact with said at least one wire embedded under said surface layer.

20. The method of claim 19 further comprising configuring a pad from a remaining excess portion of said conductive metal component deposited above said surface layer, said pad inserted on said surface layer, wherein said conductive metal component comprises at least one of: a pin, a hollow tube, a section of a tube, a folded sheet, and a grooved component.
